(19) United States
(12) Patent Application Publication
(10) Pub. No.: US 2010/0187104 A1
(43) Pub. Date: Jul. 29, 2010

(54) FILM FORMATION APPARATUS

(75) Inventor: Hiroshi Tamagaki, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Kobe Seiko Sho(Kobe Steel, Ltd.), Kobe-shi (JP)

(21) Appl. No.: 12/663,977

(22) PCT Filed: Apr. 30, 2008
(86) PCT No.: PCT/JP2008/058250

§ 371 Date: Dec. 10, 2009

(30) Foreign Application Priority Data
Jun. 25, 2007 (JP) 2007-165737

(51) Int. Cl. C23C 14/32; C23C 16/00; C23C 16/458

(52) U.S. Cl. 204/298.02; 118/728; 118/724

(57) ABSTRACT

An object of the present invention is to provide a film formation apparatus capable of easily forming a film with even thickness and being excellent in mass productivity. Therefore, the film formation apparatus is provided with a substrate holder 2 having a plurality of substrate retaining portions 7 and a film forming evaporation source 3. The film forming evaporation source 3 includes a cylindrical target 11, on a surface of the cylindrical target 11 an erosion area in a shape having two straight line portions in the parallel direction to a center axis of the cylindrical target and arc portions connecting both ends of these straight line portions is formed, and film formation particles are evaporated from this erosion area to the outside in the radial direction of the cylindrical target 11. The substrate holder 2 is moved in the aligning direction of the substrate retaining portions 7 so that respective substrates W are positioned at film formation positions where concave film formation surfaces S thereof face the erosion area.

### TECHNICAL FIELD

The present invention relates to a film formation apparatus for depositing film formation particles on a concave surface included in a half part of a sliding bearing for example so as to form a film.

### BACKGROUND ART

In recent years, due to a situation of high output power for an automobile engine and the like, durability and anti-seizing for a sliding member such as the sliding bearing become important. In general, the sliding bearing is provided with a pair of half cylindrical portions in a shape which a cylinder is divided into two, and these are combined in a tubular shape and used.

As means for improving the durability and the anti-seizing for an inner surface of such half cylindrical portion, Japanese Patent No. 2679920 (Patent Document 1) and Japanese Patent No. 2838032 (Patent Document 2) described that a film of a material excellent in a sliding property such as AlSn alloy is formed on an inner surface of a half cylindrical substrate by a physical vapor deposition method such as a sputtering method and an arc ion plating method. By the physical vapor deposition method, an evaporation source faces a concave film formation surface and vapor is supplied from this evaporation source and deposited on the concave film formation surface so as to form a film on the inner surface of the half cylindrical substrate, that is, the concave film formation surface.

However, by this physical vapor deposition method, there is a problem that uniformity of the film formed on the concave film formation surface of the half cylindrical substrate is not easily ensured. A reason thereof will be described with reference to FIG. 7 taking the sputtering method as an example.

A sputter evaporation source 31 shown in FIG. 7 is arranged so as to face a concave film formation surface S of a partial cylindrical substrate W and provided with a target and means for forming plasma P in the vicinity of a surface of the target. A sputter atom is evaporated by the plasma P from an erosion area formed at a site facing the plasma P on the target surface and scattered toward the concave film formation surface S.

However, the sputter atom is mainly discharged in the normal direction of an evaporation surface and tends to linearly move. On the concave film formation surface S, a bottom portion thereof facing straight the evaporation source 31 tends to easily receive the vapor rather than the vicinity of a circumferential edge portion. Since these tendencies are combined and multiplied, the film thickness is relatively thick on the bottom portion of the concave film formation surface S, and the thickness is thin on the vicinity of the circumferential edge portion. Further, an angle between a route of film formation particles and a film surface is shallow in the vicinity of the circumferential edge portion. Therefore, the film formed in the vicinity of the circumferential edge portion tends to be porous and fragile.

Such problems are also found in other physical vapor deposition methods apart from the sputtering method.

Therefore, Japanese Patent Laid-Open No. 2004-10915 (Patent Document 3) discloses a magnetron sputter apparatus for forming an even film on a concave film formation surface. This apparatus is provided with a magnet type target unit (a magnetron evaporation source). This target unit has a pipe having a front end formed in a rotational curved surface, a target formed on a surface of the front end and a magnet arranged inside of the pipe. The target is arranged inside of the concave film formation surface of a substrate. Sputter particles scattered from a surface of this target are deposited on the concave film formation surface so as to form the film.

Normally, the magnetron evaporation source is provided with the target and magnetic field generating means for generating a magnetic field so as to form a magnetic line penetrating into one surface of the target and out of the other surface thereof, as well as the target unit. Therefore, discharge plasma can be confined in the vicinity of the target surface by an effect of such a magnetic field. Thereby, it is possible to increase a utilization rate of a target material.

For example, a magnetron evaporation source described in Japanese Patent Laid-Open No. 1993-295536 (Patent Document 4) and FIG. 6 of Japanese Patent Laid-Open No. 2003-96562 (Patent Document 5) is provided with a straight center magnets arranged on the back surface side of a target and outer magnets arranged so as to surround the center magnet. The center magnet and the outer magnets have different polarities from each other, and form a magnetic line penetrating the target so as to connect the center magnet and the outer magnets in an area between both the magnets.

A magnetic field in which this magnetic line is formed has a shape including two straight line portions and arc portions connecting both ends of the straight line portions. Therefore, the magnetic field is called as a race-track magnetic field. Since the discharge plasma is confined in this race-track magnetic field, discharge plasma in a race-track shape is formed in the vicinity of the surface of the target. A wide erosion area in the race-track shape is formed on the target surface facing this race-track shaped plasma.

However, by the sputter apparatus described in Patent Document 3, since there is a need for forming the film for each substrate, production efficiency is inferior.

### [Patent Document 1] Japanese Patent No. 2679920

### [Patent Document 2] Japanese Patent No. 2838032

### [Patent Document 3] Japanese Patent Laid-Open No. 2004-10915

### [Patent Document 4] Japanese Patent Laid-Open No. 1993-295536

### [Patent Document 5] Japanese Patent Laid-Open No. 2003-96562 (FIG. 6)

### DISCLOSURE OF THE INVENTION

The present invention is achieved in consideration with the above problems. An object of the present invention is to provide a film formation apparatus for forming a film on a concave film formation surface of a substrate such as a half cylindrical member forming a sliding bearing, the apparatus capable of easily forming a film with even thickness and being excellent in mass productivity.

Therefore, a film formation apparatus according to the present invention is provided with a substrate holder having a plurality of substrate retaining portions for retaining a plurality of substrates having concave film formation surfaces respectively, and a film forming evaporation source including a cylindrical target serving as a material of film formation particles, on a surface of the cylindrical target an erosion area in a shape having two straight line portions in the parallel direction to a center axis of the cylindrical target and arc portions connecting both ends of these straight line portions is formed, and the film formation particles are evaporated from this erosion area to the outside in the radial direction of the cylindrical target.

The substrate retaining portions in the substrate holder are arranged so that the substrate retaining portions are aligned in the circumferential direction on a cylinder surface having a center axis parallel to the center axis of the cylindrical target and the concave film formation surfaces of the substrates retained by the substrate retaining portions are placed outward in the radial direction of the cylinder surface. The substrate holder is installed within the vacuum chamber rotatably around the center axis of the cylinder surface so that the substrates are respectively positioned at film formation positions where the concave film formation surfaces of the substrates respectively retained by the substrate retaining portions face the erosion area and the film formation particles evaporated from the erosion area are deposited on the concave film formation surfaces.

Alternatively, the substrate retaining portions in the substrate holder may be arranged so that the substrate retaining portions are aligned in the direction orthogonal to the center axis of the cylindrical target on a flat surface parallel to the center axis of the cylindrical target and the concave film formation surfaces of the substrates retained by the substrate retaining portions are placed toward the side of the cylindrical target. The substrate holder may be installed within the vacuum chamber linearly movably along the aligning direction of the substrate retaining portions so that the substrates are respectively positioned at film formation positions where the concave film formation surfaces of the substrates respectively retained by the substrate retaining portions face the erosion area and the film formation particles evaporated from the erosion area are deposited on the concave film formation surfaces.

According to the film formation apparatus, the film formation particles evaporated from the erosion area on the surface of the cylindrical target are discharged in the normal direction of the erosion area. Therefore, the discharging direction of the film formation particles is expanded in comparison to a flat plate type evaporation source. This allows evenly depositing the film formation particles evaporated and discharged from the erosion area formed on the surface of the cylindrical target on sites of the concave film formation surfaces even when curvature of the concave film formation surfaces of the substrates is more or less changed.

Further, rotation or linear movement of the substrate holder allows positioning the respective substrates at the film formation positions where the concave film formation surfaces of the substrates face the erosion area and the film formation particles evaporated from the erosion area are deposited on the concave film formation surfaces. Thereby, efficiency of forming the film on the concave film formation surfaces of a plurality of the substrates is increased.

### BRIEF DESCRIPTION OF THE DRAWINGS

FIG. 1 A sectional plan view of a major part of a film formation apparatus according to a first embodiment of the present invention.

FIG. 2 FIG. 2(A): a perspective view showing a stack formed by laminating a plurality of partial cylindrical substrates; and FIG. 2(B): a perspective view of a holder main body retaining the stack.

FIG. 3 A partially enlarged sectional view showing a vicinity part of a retaining concave portion of the holder main body.

FIG. 4 A schematic front view of a magnet forming a magnetic field generating device provided inside of a cylindrical target of the film formation apparatus.

FIG. 5 A sectional plan view showing the holder main body and a cylindrical magnetron sputter evaporation source in a state that the magnetic field generating device is moved in the circumferential direction of the cylindrical target.

FIG. 6 A sectional plan view of a major part of a film formation apparatus according to a second embodiment of the present invention.

FIG. 7 A sectional view showing a state of forming a film on a concave film formation surface of a conventional partial cylindrical substrate.

### BEST MODES FOR CARRYING OUT THE INVENTION

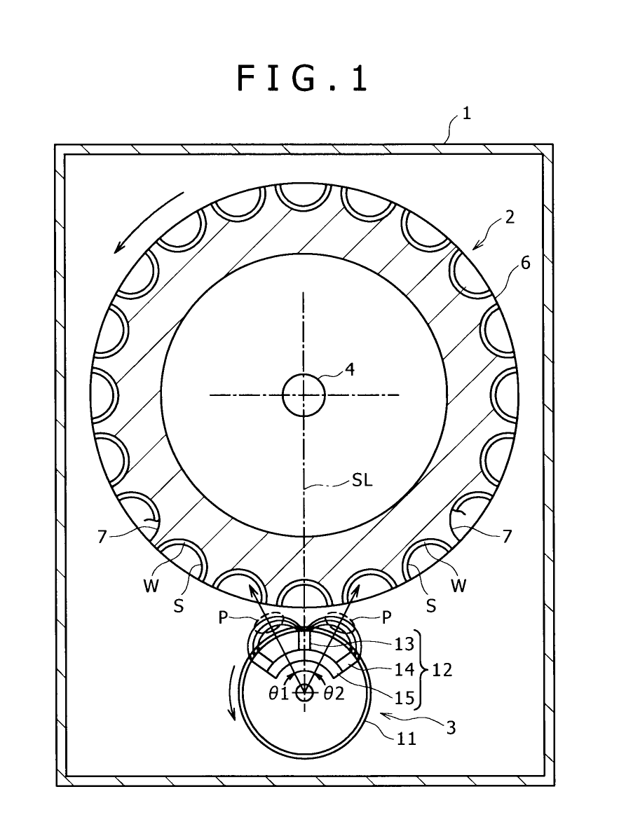

Hereinafter, a sputter film formation apparatus according to a first embodiment of the present invention will be described with reference to FIGS. 1 to 5.

A sputter film formation apparatus shown in FIG. 1 is provided with a vacuum chamber 1, a substrate holder 2 provided within the vacuum chamber 1, and a magnetron sputter evaporation source 3. The substrate holder 2 retains a plurality of partial cylindrical substrates W having concave film formation surfaces S respectively. The magnetron sputter evaporation source 3 deposits film formation particles on the concave film formation surfaces S of the partial cylindrical substrates W so as to form films.

A sputter power source (not shown) for supplying sputter electric power to the evaporation source 3 is connected to the magnetron sputter evaporation source 3. A decompressor and a sputtering gas supply device for maintaining the inside of the vacuum chamber 1 at a predetermined gas pressure are connected to the vacuum chamber 1. At the time of forming the film, sputtering gas (discharge gas) such as argon gas is introduced into the vacuum chamber 1 normally to about 0.01 to 10 Pa. Since known devices can be applied to both the decompressor and the sputtering gas supply device, the devices are not shown.

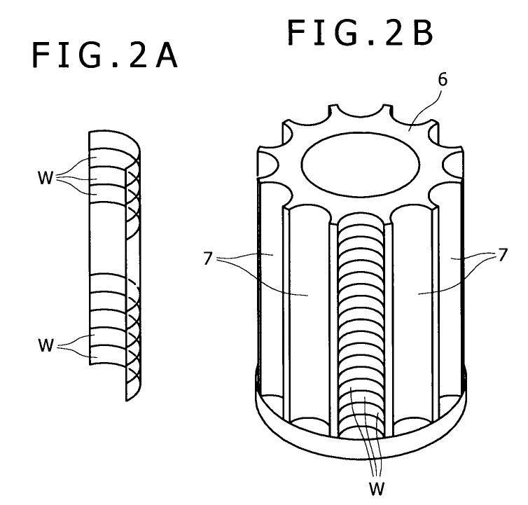

Typically, the partial cylindrical substrates W may be half cylindrical substrates of a sliding bearing having a half-divided structure. In a case of a sliding bearing for an automobile engine, a diameter of a half cylinder is about 50 mm and height thereof is about 15 mm. As shown in FIG. 2(A), the partial cylindrical substrates W with such size can be retained by the substrate holder 2 in a state that the partial cylindrical substrates W are laminated onto each other in the cylindrical axial direction so as to form a stack. However, a shape of the substrates which are targeted for film formation in the present invention is not particularly limited apart from a condition of having the concave film formation surfaces. The shape may be concave reflecting mirrors for example in addition to the partial cylindrical substrates.

The substrate holder 2 is provided with a cylindrical holder main body 6 and a rotation center shaft 4 positioned on a center axis thereof, and supported on the vacuum chamber 1 so as to be rotatable around this rotation center shaft 4, and more preferably rotated and driven by drive means such as a motor.

As shown in FIG. 2(B), a plurality of retaining concave portions (substrate retaining portions) 7 for retaining the stacks formed by the partial cylindrical substrates W are aligned on a circumferential surface (a cylinder surface) of the holder main body 6 in the circumferential direction of the holder main body 6. The retaining concave portion 7 has a bottom surface in a half cylindrical shape (that is, a shape forming a part of a cylindrical surface) into which the stack can be fitted. A center axis of the retaining concave portions 7 is formed so as to be parallel to the rotation center shaft 4. More specifically, the concave film formation surfaces S of the partial cylindrical substrates W are fitted into the retaining concave portions 7 in a state that the concave film formation surfaces S are placed outward in the radial direction of a circumferential surface of the holder main body 6 so that the stack formed by the partial cylindrical substrates W is retained by the holder main body 6.

In the apparatus shown in the drawing, in order to easily load the partial cylindrical substrates W into the retaining concave portions 7, the substrate holder 2 is installed in a state that the rotation center shaft 4 is placed in the vertical direction. However, the rotation center shaft 4 of the substrate holder 2 may be placed in the other directions. The substrate retaining portions formed in the holder main body 6 are not limited to the retaining concave portions 7 but may be portions capable of retaining substrates having concave film formation surfaces.

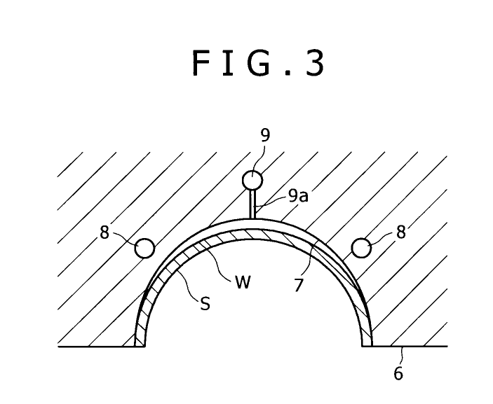

As shown in FIG. 3, a cooling water passage 8 and a gas passage 9 extending in parallel to the retaining concave portion 7 are formed in the holder main body 6. The cooling water passage 8 is provided at a position where at least the retaining concave portion 7 and a site in the vicinity thereof in the holder main body 6 can be cooled. An injection hole 9a extends from the gas passage 9 to the bottom surface of the retaining concave portion 7. Through the gas passage 9 and the injection hole 9a, inert gas for thermal transmission such as helium and argon is supplied to space positioned between the bottom surface of the retaining concave portion 7 and the stack of the partial cylindrical substrates W which is retained by the retaining concave portion 7. This gas promptly transmits heat generated in the partial cylindrical substrates W at the time of forming the film to the holder main body 6. This facilitation of the thermal transmission can be also achieved by providing a soft metallic member excellent in thermal conductivity such as aluminum and indium in the space in addition to supplying the gas for the thermal transmission. These thermal transmission facilitating means are not necessarily provided in the present invention.

The magnetron sputter evaporation source 3 has a cylindrical target 11, a magnetic field generating device 12 provided inside of the cylindrical target 11 and rotation fixing means (not shown) for fixing the magnetic field generating device 12.

The cylindrical target 11 is arranged so that a center axis thereof is parallel to the rotation center shaft 4 of the substrate holder 2 and the cylindrical target 11 is rotatable around the center axis. The magnetic field generating device 12 is arranged rotatably around the center axis of the cylindrical target 11 independently from the cylindrical target 11. The rotation fixing means fixes the magnetic field generating device 12 at an arbitrary rotation position.

The magnetic field generating device 12 is to generate a race-track shape magnetic field at the time of forming the film so as to form an erosion area in a race-track shape on a surface of the cylindrical target 11, and provided with a center magnet 13, an outer magnet 14 and a magnetic short-circuit member 15 for magnetically connecting these magnets 13 and 14.

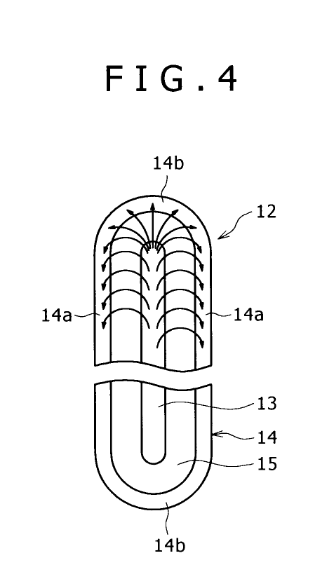

As shown in FIG. 4, the center magnet 13 has a shape extending in one direction and is arranged so that the longitudinal direction thereof is parallel to the center axis of the cylindrical target 11. The outer magnet 14 is formed in a race-track shape surrounding the center magnet 13. That is, the outer magnet 14 has two straight portions 14a extending on both the left and right sides of the center magnet 13 in parallel to this and arc portions 14b connecting both ends of these straight portions 14a. The center magnet 13 and the outer magnet 14 are arranged so as to have different polarities from each other for forming a magnetic line bridging both the magnets 13 and 14 while passing through the cylindrical target 11 along race-track shape space between both the magnets 13 and 14. The magnetic short-circuit member 15 is arranged radial inside of both the magnets 13 and 14 and has an arc section bridging both the magnets 13 and 14.

A magnetic field in which the magnetic line in the above mode is formed is called the race-track shape magnetic field. However, the magnetic field formed by the magnetic field generating device according to the present invention is not limited to the race-track shape magnetic field. For example, a magnetic field having an erosion area also inside of the race-track shape area may be formed. Further, the two straight line portions of the formed magnetic line are not necessarily accurately parallel, and the parts connecting these straight line portions are not necessarily an accurate arc. That is, the race-track shape has to be formed as a whole and some distortion is acceptable.

As a material of the magnets 13 and 14 of the magnetic field generating device 12, a magnet having large residual flux density such as a samarium-cobalt magnet and a neodymium magnet is preferable. However, it is possible to use other kinds of magnets such as a ferrite magnet and a superconductive magnet, and an electromagnet. A plurality of magnetic sources may be combined, for example a permanent magnet and the electromagnet may be combined.

When the race-track shape magnetic field is formed, the cylindrical target 11 is used as a cathode of glow discharge, and discharge plasma is generated by the glow discharge. This discharge plasma is confined in the race-track shape magnetic field in the vicinity of the surface of the cylindrical target 11. As a result, discharge plasma P in a race-track shape is formed, and an area where film formation particles are sputter-evaporated, that is, the erosion area in a race-track shape is formed on the surface of the cylindrical target 11 along this discharge plasma P.

An outer diameter of the cylindrical target 11 is normally about 100 to 250 mm, and generally set to be about 130 to 200 mm. Axial length of the cylindrical target 11 is more preferably set so that straight line portions of the erosion area on the surface of the cylindrical target 11 face the whole stack. In general, the length is preferably about 20 to 40 cm longer than total length of the stack of the partial cylindrical substrates W set in the substrate holder 2.

An erosion part formed by the plasma P in a race-track shape has arc portions on both ends and two straight line portions placed between the arc portions. A certain degree of gap is generated between both the straight line portions. Although this gap is adjustable by a diameter of the cylindrical target 11 and design of the magnetic field, the gap is typically about 30 to 100 mm.

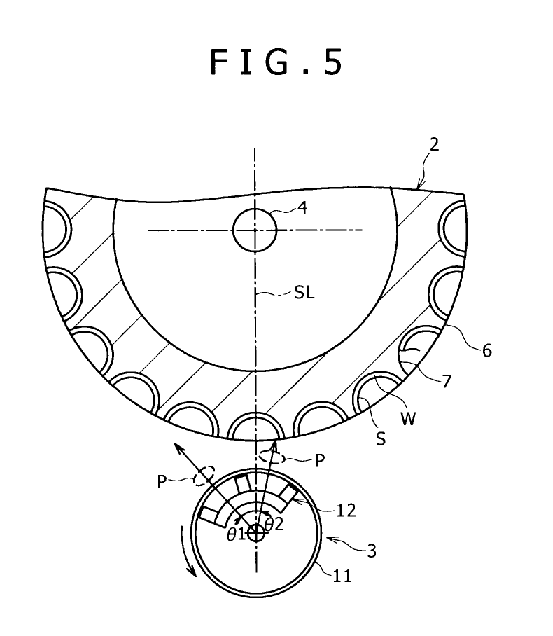

As shown in FIGS. 1 and 5, the normal directions in the straight line portions of the erosion area formed on the surface of the cylindrical target 11, that is, the directions of straight lines connecting the straight line portions of the erosion area formed on the surface of the cylindrical target 11 and the center axis of the cylindrical target 11 on a flat surface perpendicular to the center axis of the cylindrical target 11 (hereinafter, sometimes referred to as the “discharge vapor center lines”) make predetermined angles θ1 and θ2 to a reference line SL connecting the rotation center shaft 4 of the substrate holder 2 and the center axis of the cylindrical target 11 as shown in FIG. 1. In a case where the center magnet 13 of the magnetic field generating device 12 is positioned on the reference line SL, θ1 is equal to θ2. In general, (θ1+θ2) is set to be about 20 to 80°. It should be noted that in a case where the erosion area is not formed in a race-track shape but a solid oval shape, it is considered that a plurality of straight portions closely exist in the area. Thus, the angles of the discharge vapor center lines to the reference line may be determined in accordance with the straight line portions on the most outer side.

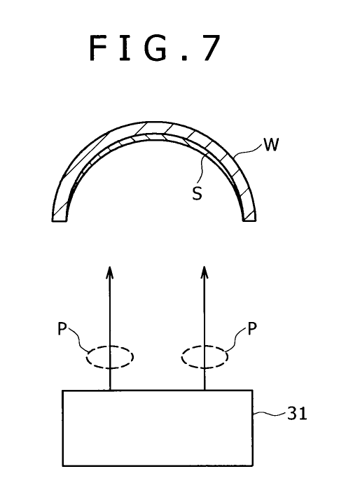

At the time of sputter film formation, when the cylindrical magnetron sputter evaporation source 3 is used, it is possible to expand the discharge direction of the vapor sputter-evaporated from the straight line portions of the erosion area relative to the reference line in comparison to a case where a conventional flat plate shape magnetron evaporation source (such as a sputter evaporation source 31 in FIG. 7) is used. This allows increasing a vapor amount toward the vicinity of circumferential edges of the concave film formation surfaces S in the partial cylindrical substrates W loaded in the substrate holder 2 so as to suppress unevenness of film thickness due to a difference in sites of the film formation surfaces.

In a state that a position of the magnetic field generating device 12 is fixed, the cylindrical target 11 can be rotated independently from this magnetic field generating device 12. This rotation allows forming the film while displacing a site where the erosion area is formed by the discharge plasma P and the magnetic field generating device 12 on the surface of the cylindrical target 11. This allows improving a utilization rate of a target material.

Further, rotation of the substrate holder 2 allows successively positioning the partial cylindrical substrates W respectively retained by the retaining concave portions 7 at predetermined film formation positions, that is, at positions where the concave film formation surfaces S face the erosion area and the film formation particles evaporated from the erosion area are deposited on the concave film formation surfaces. This remarkably improves efficiency of forming the film on the concave film formation surfaces S.

Meanwhile, the magnetic field generating device 12 is movable in the circumferential direction of the cylindrical target 11 separately from the cylindrical target 11. Therefore, as shown in FIG. 5, it is possible to change the direction of the plasma in a race-track shape for sputtering the target surface relative to the reference line in the circumferential direction. This allows properly changing an angle of the cylindrical target 11 in the circumferential direction for a predetermined time or the predetermined rotation number of the substrate holder 2 so as to change discharge angles of the vapor, that is, the angles θ1 and θ2 between the discharge vapor center lines and the reference line. Thereby, it is possible to more improve evenness of the film thickness.

In an example shown in FIG. 5, θ1 is larger than θ2. The discharge vapor in the area where the larger angle θ1 is made is mainly deposited on circumferential edge portions of the concave film formation surfaces S of the partial cylindrical substrates W. Therefore, this angle θ1 may be set to be large within a range where the discharge vapor center lines reach the vicinity of the circumferential edges of the concave film formation surfaces S. Meanwhile, the discharge vapor in the area where the smaller angle θ2 is made is mainly deposited in bottom portions of the concave film formation surfaces S. Therefore, it is possible to freely set the angle θ2 within a range smaller than the angle θ1. Indeed, a degree of (θ1+θ2) is determined by arrangement of the center magnet 13 and the outer magnet 14. Therefore, when the angle θ1 (or θ2) is determined, the other angle θ1 (or θ2) is automatically determined. As a matter of course, after changing to (θ1>θ2) as shown in the drawing, it is advisable to move the magnetic field generating device 12 to the opposite side so that θ2 is larger than θ1 in order to make both ends of the circumferential edges of the concave film formation surfaces S of the partial cylindrical substrates S have even film thickness. In a case where the film formation apparatus is used while fixing the magnetic field generating device 12 at a position shown in FIG. 1, the film is mainly formed on only one-side parts among the vicinity of the circumferential edges of the concave film formation surfaces S. Therefore, a magnetron sputter evaporation source provided with other cylindrical target may be arranged so as to be symmetrical to the reference line.

A favorable angle range of the angle θ1 or θ2 (hereinafter, simply referred to as the “angle θ”) depends on a diameter of the holder main body 6. However, since the actual diameter of the holder main body 6 is about 0.6 to 1.5 m, the angle θ is preferably about 10 to 40° in this case. The angle θ is more preferably about 15 to 30°. When the angle θ is less than 10°, the vapor discharged from the straight line portions of the other erosion area is not sufficiently deposited onto the vicinity of the circumferential edges of the concave film formation surfaces S. Meanwhile, when the angle θ exceeds 40°, the vapor discharged from the straight line portions of the one erosion area is released to outside of the holder main body 6. Therefore, the efficiency of forming the film is lowered.

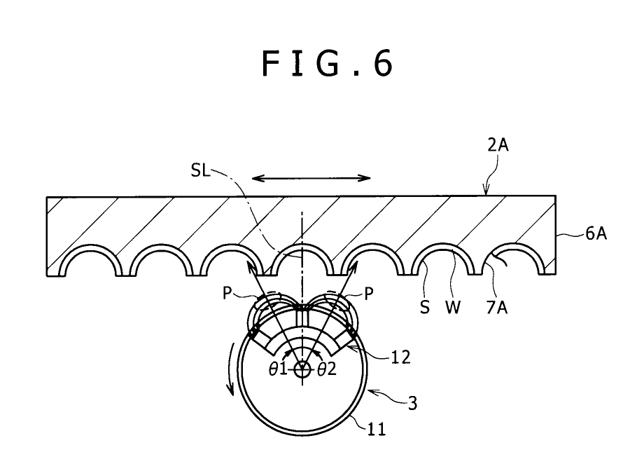

Next, a film formation apparatus according to a second embodiment of the present invention will be described with reference to FIG. 6. A difference in a configuration between this second embodiment and the first embodiment is only a configuration of the substrate holder. Therefore, a description will be given taking this as a center. The same members as in the film formation apparatus of the first embodiment will be given the same reference numerals and a description thereof will be simplified or omitted.

The film formation apparatus according to this second embodiment is provided with a cuboid substrate holder 2A instead of the cylindrical substrate holder 2. This substrate holder 2A is installed within the vacuum chamber 1 so as to be linearly movable in the horizontal direction in an example of the drawing, and driven in the same direction by a drive mechanism (not shown). This substrate holder 2A has a flat side surface facing the cylindrical target 11 (a flat surface parallel to the center axis of the cylindrical target 11). A plurality of retaining concave portions 7A aligned in the horizontal direction, that is, the moving direction thereof are formed on this side surface. The stack formed by a plurality of the partial cylindrical substrates W is fitted into the retaining concave portion 7A. In the stack, these partial cylindrical substrates W are laminated in a state that center axes of the concave film formation surfaces S of the partial cylindrical substrates W correspond to each other. In this state, these partial cylindrical substrates W are retained in the retaining concave portions 7A.

The magnetron sputter evaporation source 3 according to this second embodiment is arranged in front of the substrate holder 2A. The cylindrical target 11 of this magnetron sputter evaporation source 3 is standingly installed so as to face the retaining concave portions 7A in a state that the center axis of the cylindrical target 11 is placed in the up and down direction. In other words, the retaining concave portions 7 of the substrate holder 2 are aligned on the flat surface parallel to the center axis of the cylindrical target 11 (a perpendicular surface in this embodiment) in the direction orthogonal to the center axis (the left and right direction in this embodiment), and retain the partial cylindrical substrates W so that the concave film formation surfaces thereof are placed toward the side of the cylindrical target 11. The substrate holder 2 is installed within the vacuum chamber 1 so as to be linearly movable along the aligning direction of these retaining concave portions 7.

In this second embodiment, by linear movement of the substrate holder 2, it is also possible to successively position the partial cylindrical substrates W respectively retained by the retaining concave portions 7 at predetermined film formation positions, that is, at positions where the concave film formation surfaces S face the erosion area and the film formation particles evaporated from the erosion area are deposited on the concave film formation surfaces. Thereby, it is possible to remarkably improve the efficiency of forming the film on the concave film formation surfaces S.

In this second embodiment, a reference line SL passing through a center line of the cylindrical target 11 in the direction perpendicular to the movement direction of a holder main body 6A is provided on the flat surface perpendicular to the center axis of the cylindrical target 11. As well as the first embodiment, the magnetic field generating device 12 of the magnetron sputter evaporation source 3 forms the race-track magnetic field having the two straight line portions and the arc portions on both the ends. The straight lines connecting the straight line portions of the erosion area formed on the surface of the cylindrical target 11 by the straight line portions and the center axis of the cylindrical target 11, that is, the discharge vapor center lines make the angles θ1 and θ2 to the reference line SL as well as the first embodiment. The retaining concave portions 7A of the holder main body 6A according to this second embodiment are aligned on the flat surface. Therefore, even when the angle θ1 or θ2 is relatively larger than the first embodiment, it is possible to deposit sputter particles in the vicinity of the circumferential edges of the concave film formation surfaces S of the partial cylindrical substrates W loaded in the holder main body 6A. Indeed, when the film with even film thickness is formed in the vicinity of the circumferential edges of the concave film formation surfaces S while effectively utilizing sputter vapor generated from the erosion area of the cylindrical target 11, the angles are desirably set to be about 10 to 50°, preferably about 10 to 40°, and more preferably about 15 to 35°.

The film formation apparatus according to the first and second embodiment is a sputter apparatus having the cylindrical target 11 as a sputter evaporation source and depositing the film formation particles discharged from the surface of the cylindrical target 11 on the concave film formation surfaces S of the partial cylindrical substrates W so as to form the film. However, the film formation apparatus according to the present invention may be an arc ion plating (AIP) apparatus having the cylindrical target as an arc evaporation source and depositing film formation particles evaporated and ionized from an evaporation surface of the cylindrical target 11 by arc discharge on the concave film formation surfaces S of the partial cylindrical substrates W on which negative bias voltage is applied so as to form the film. In this case as well, since the magnetic field generating device such as a magnet and a magnetic coil is arranged inside of the cylindrical target so as to form the race-track shape magnetic field elongated in the center axial direction, it is possible to perform race-track shaped scan for an arc spot. Thereby, it is possible to form an erosion area in a race-track shape. This erosion area is also not limited to a race-track shape but may be a solid oval shape including an inner part of a part in a race-track shape.

In the cylindrical evaporation source, at least one of angles between straight lines connecting the center axis of the cylindrical target and straight line portions of the erosion area and a reference line connecting the center axis of the holder main body and the center axis of the cylindrical target on a flat surface perpendicular to the center axis of the cylindrical target is preferably within a range from 10 to 40°.

As mentioned above, according to the film formation apparatus of the present invention, the film formation particles evaporated from the erosion area on the surface of the cylindrical target are discharged in the normal direction of the erosion area. Therefore, the discharging direction of the film formation particles is expanded in comparison to a conventional flat plate type evaporation source. Thus, it is possible to evenly deposit the film formation particles discharged from the erosion area on the concave film formation surfaces of the substrates retained by the substrate holder. In the cylindrical target, since the erosion area is formed in a wide range along the axial direction thereof, the utilization rate of the target is increased and productivity is excellent. Further, the rotation or the linear movement of the substrate holder allows positioning the respective substrates at the film formation positions where the concave film formation surfaces of the substrates face the erosion area and the film formation particles evaporated from the erosion area are deposited on the concave film formation surfaces. This allows increasing the efficiency of forming the film on the concave film formation surfaces of a plurality of the substrates.

With adopting the cylindrical target, in a case where a plurality of the substrates are retained by the substrate retaining portions of the substrate holder in a state that the substrates are piled up, it is possible to form the film on the concave film formation surfaces of a plurality of the substrates at the same time. Therefore, mass productivity is increased.

With regard to the substrate holder, the substrate retaining portions are the retaining concave portions having the bottom surfaces forming a part of a cylindrical surface, and the substrates are fitted into the bottom surfaces. These retaining concave portions are more preferably aligned in the direction orthogonal to the center axis of the cylinder surface. Arrangement of these retaining concave portions is a compact structure and allows positioning the substrates retained by the substrate retaining portions at the film formation positions.

Specifically, the substrate retaining portions in the substrate holder may be arranged so that the substrate retaining portions are aligned in the circumferential direction on the cylinder surface having the center axis parallel to the center axis of the cylindrical target and the concave film formation surfaces of the substrates retained by the substrate retaining portions are placed outward in the radial direction of the cylinder surface. The substrate holder may be installed within the vacuum chamber rotatably around the center axis of the cylinder surface so that the substrates are respectively positioned at the film formation positions where the concave film formation surfaces of the substrates respectively retained by the substrate retaining portions face the erosion area and the film formation particles evaporated from the erosion area are deposited on the concave film formation surfaces. This substrate holder allows successively positioning the substrates retained by the substrate retaining portions at the film formation positions only by the rotation around the center axis of the substrate holder.

In this case, in the film forming evaporation source, the erosion area is favorably formed within a range where on the flat surface perpendicular to the center axis of the cylindrical target, at least one of angles between the straight lines connecting the center axis of the cylindrical target and the straight line portions of the erosion area and the reference line connecting the rotation center shaft of the substrate holder and the center axis of the cylindrical target is 10 to 40°.

Alternatively, the substrate retaining portions in the substrate holder may be arranged so that these substrate retaining portions are aligned in the direction orthogonal to the center axis of the cylindrical target on the flat surface parallel to the center axis of the cylindrical target and the concave film formation surfaces of the substrates retained by the substrate retaining portions are placed toward the side of the cylindrical target. The substrate holder may be installed within the vacuum chamber linearly movably along the aligning direction of the substrate retaining portions so that the substrates are respectively positioned at the film formation positions where the concave film formation surfaces of the substrates respectively retained by the substrate retaining portions face the erosion area and the film formation particles evaporated from the erosion area are deposited on the concave film formation surfaces.

In this case, in the film forming evaporation source, the erosion area is favorably formed within a range where on the flat surface perpendicular to the center axis of the cylindrical target, at least one of angles between the straight lines connecting the center axis of the cylindrical target and the straight line portions of the erosion area and the reference line passing through the center axis of the cylindrical target and being provided in the direction perpendicular to the moving direction of the substrate holder is 10 to 50°.

Preferably, the film forming evaporation source further includes the magnetic field generating device arranged inside of the cylindrical target for generating the magnetic field for forming the erosion area on the surface of the cylindrical target. This magnetic field generating device allows forming the erosion area on the surface of the cylindrical target while allowing the surface of the cylindrical target to face the concave film formation surfaces of the substrates retained by the substrate holder.

This magnetic field generating device may be provided movably along the circumferential direction of the cylindrical target so as to move the erosion area in the circumferential direction of the cylindrical target. This movement of the magnetic field generating device and the movement of the erosion area in the circumferential direction in accordance with the movement of the device change the discharge direction of the vapor discharged from the erosion area. Thereby, it is possible to more improve the uniformity of the film at the sites of the concave film formation surfaces of the substrates.

The cylindrical target of the film forming evaporation source is preferably provided rotatably around the center axis of the cylindrical target independently from the magnetic field generating device. This rotation allows changing the site where the erosion area is formed in the circumferential direction on the surface of the cylindrical target. This change allows widening a range that the surface of the cylindrical target is utilized as the evaporation source and more improving the utilization rate of the cylindrical target. For example, it is possible to use the whole circumference of the surface of the cylindrical target as the evaporation source.

The substrate holder may be provided with cooling means for cooling at least the substrate retaining portions of this substrate holder. This cooling suppresses a temperature increase of the substrates in accordance with the film formation and improves the uniformity of the film.

The substrate holder may be provided with thermal transmission facilitating means for facilitating thermal transmission between the substrate retaining portions and the substrates retained by the substrate retaining portions. This thermal transmission facilitating means efficiently releases heat generated in the substrates retained by the substrate retaining portions to the side of the substrate holder at the time of forming the film. Thereby, it is possible to further suppress the temperature increase of the substrates in accordance with the film formation and more improve film quality.

The film formation apparatus according to the present invention may be the sputter apparatus in which the film forming evaporation source is the sputter evaporation source and the film formation particles sputter-evaporated from the surface of the cylindrical target are deposited on the concave film formation surfaces of the substrates so as to form the film. Alternatively, the film formation apparatus may be the arc ion plating apparatus in which the film forming evaporation source is the arc evaporation source and the film formation particles evaporated and scattered from the surface of the cylindrical target by the arc discharge are deposited on the concave film formation surfaces of the substrates so as to form the film.

1. A film formation apparatus for depositing film formation particles on concave film formation surfaces respectively included in a plurality of substrates within a vacuum chamber so as to form films, comprising:
a substrate holder having a plurality of substrate retaining portions for retaining the substrates; and
a film forming evaporation source including a cylindrical target serving as a material of the film formation particles, on a surface of the cylindrical target an erosion area in a shape having two straight line portions in the parallel direction to a center axis of the cylindrical target and arc portions connecting both ends of the straight line portions being formed, and the film formation particles being evaporated from the erosion area to the outside in the radial direction of the cylindrical target, wherein
said substrate retaining portions in said substrate holder are arranged so that said substrate retaining portions are aligned in the circumferential direction on a cylinder surface having a center axis parallel to the center axis of the cylindrical target, and the concave film formation surfaces of the substrates retained by said substrate retaining portions are placed outward in the radial direction of the cylinder surface, and
said substrate holder is installed within the vacuum chamber rotatably around the center axis of the cylinder surface so that the substrates are respectively positioned at film formation positions where the concave film formation surfaces of the substrates respectively retained by said substrate retaining portions face the erosion area and the film formation particles evaporated from the erosion area are deposited on the concave film formation surfaces.

2. The film formation apparatus according to claim 1, wherein
in said film forming evaporation source, the erosion area is formed within a range where on a flat surface perpendicular to the center axis of the cylindrical target, at least one of angles between straight lines connecting the center axis of the cylindrical target and the straight line portions of the erosion area and a reference line connecting a rotation center shaft of said substrate holder and the center axis of the cylindrical target is 10 to 40°.

3. The film formation apparatus according to claim 1, wherein
said substrate retaining portions are retaining concave portions having bottom surfaces forming a part of a cylindrical surface, the substrates being fitted onto said bottom surfaces, and
said retaining concave portions are aligned in the direction orthogonal to the center axis of the cylinder surface.

4. The film formation apparatus according to claim 1, wherein
said film forming evaporation source further includes a magnetic field generating device arranged inside of the cylindrical target for generating a magnetic field for forming the erosion area on the surface of the cylindrical target.

5. The film formation apparatus according to claim 4, wherein
said magnetic field generating device of said film forming evaporation source is provided movably along the circumferential direction of the cylindrical target so as to move the erosion area in the circumferential direction of the cylindrical target.

6. The film formation apparatus according to claim 4, wherein
the cylindrical target of said film forming evaporation source is provided rotatably around the center axis of the cylindrical target independently from said magnetic field generating device.

7. The film formation apparatus according to claim 1, wherein
cooling means for cooling at least said substrate retaining portions of said substrate holder is additionally provided in said substrate holder.

8. The film formation apparatus according to claim 1, wherein
thermal transmission facilitating means for facilitating thermal transmission between said substrate retaining portions and the substrates retained by said substrate retaining portions is provided in said substrate holder.

9. The film formation apparatus according to claim 1, wherein
said film forming evaporation source is a sputter evaporation source, and
the film formation particles sputter-evaporated from the surface of the cylindrical target are deposited on the concave film formation surfaces of the substrates so as to form the films.

10. The film formation apparatus according to claim 1, wherein
the cylindrical target is an arc evaporation source, and
the film formation particles evaporated and scattered from the surface of the cylindrical target by arc discharge are deposited on the concave film formation surfaces of the substrates so as to form the films.

11. A film formation apparatus for depositing film formation particles on concave film formation surfaces respectively included in a plurality of substrates within a vacuum chamber so as to form films, comprising:
a substrate holder having a plurality of substrate retaining portions for retaining the substrates; and
a film forming evaporation source including a cylindrical target serving as a material of the film formation particles, on a surface of the cylindrical target an erosion area in a shape having two straight line portions in the parallel direction to a center axis of the cylindrical target and arc portions connecting both ends of the straight line portions being formed, and the film formation particles being evaporated from the erosion area to the outside in the radial direction of the cylindrical target, wherein
said substrate retaining portions in said substrate holder are arranged so that said substrate retaining portions are aligned in the direction orthogonal to the center axis of the cylindrical target on a flat surface parallel to the center axis of the cylindrical target and the concave film formation surfaces of the substrates retained by said substrate retaining portions are placed toward the side of the cylindrical target, and
said substrate holder is installed within the vacuum chamber linearly movably along the aligning direction of said substrate retaining portions so that the substrates are respectively positioned at film formation positions where the concave film formation surfaces of the substrates respectively retained by said substrate retaining portions face the erosion area and the film formation particles evaporated from the erosion area are deposited on the concave film formation surfaces.

12. The film formation apparatus according to claim 11, wherein
in said film forming evaporation source, the erosion area is formed within a range where on a flat surface perpendicular to the center axis of the cylindrical target, at least one of angles between straight lines connecting the center axis of the cylindrical target and the straight line portions of the erosion area and a reference line passing through the center axis of the cylindrical target and extending in the direction perpendicular to the moving direction of said substrate holder is 10 to 50°.

13. The film formation apparatus according to claim 11, wherein
said substrate retaining portions are retaining concave portions having bottom surfaces forming a part of a cylindrical surface, the substrates being fitted onto said bottom surfaces, and
said retaining concave portions are aligned in the direction orthogonal to a center axis of the cylinder surface.

14. The film formation apparatus according to claim 11, wherein
said film forming evaporation source further includes a magnetic field generating device arranged inside of the cylindrical target for generating a magnetic field for forming the erosion area on the surface of the cylindrical target.

15. The film formation apparatus according to claim 14, wherein
said magnetic field generating device of said film forming evaporation source is provided movably along the circumferential direction of the cylindrical target so as to move the erosion area in the circumferential direction of the cylindrical target.

16. The film formation apparatus according to claim 14, wherein
the cylindrical target of said film forming evaporation source is provided rotatably around the center axis of the cylindrical target independently from said magnetic field generating device.

17. The film formation apparatus according to claim 11, wherein
cooling means for cooling at least said substrate retaining portions of said substrate holder is additionally provided in said substrate holder.

18. The film formation apparatus according to claim 11, wherein
thermal transmission facilitating means for facilitating thermal transmission between said substrate retaining portions and the substrates retained by said substrate retaining portions is provided in said substrate holder.

19. The film formation apparatus according to claim 11, wherein
said film forming evaporation source is a sputter evaporation source, and
the film formation particles sputter-evaporated from the surface of the cylindrical target are deposited on the concave film formation surfaces of the substrates so as to form the films.

20. The film formation apparatus according to claim 11, wherein
the cylindrical target is an arc evaporation source, and
the film formation particles evaporated and scattered from the surface of the cylindrical target by arc discharge are deposited on the concave film formation surfaces of the substrates so as to form the films.
